(19) United States
(12) Patent Application Publication
(10) Pub. No.: US 2024/0099067 A1
(43) Pub. Date: Mar. 21, 2024

(54) DISPLAY DEVICE

(71) Applicant: Samsung Display Co., LTD., Yongin-si (KR)

(72) Inventors: JUN HYEONG PARK, Yongin-si (KR); Sang Woo KIM, Yongin-si (KR)

(21) Appl. No.: 18/232,764

(22) Filed: Aug. 10, 2023

(30) Foreign Application Priority Data
Sep. 21, 2022 (KR) 10-2022-0119615

(51) Int. Cl. H10K 59/122; H10K 59/80

(52) U.S. Cl. CPC H10K 59/122; H10K 59/80515

(57) ABSTRACT

A display device includes: a substrate; a pixel circuit driving portion that is on the substrate; an organic layer that covers the pixel circuit driving portion; a light emitting element on the organic layer and including an anode; and a separator including a reverse tapered side on the organic layer, wherein a width of a bottom surface of the separator is equal to a distance between adjacent anodes.

### CROSS-REFERENCE TO RELATED APPLICATION

The present application claims priority to and the benefit of Korean Patent Application No. 10-2022-0119615 filed in the Korean Intellectual Property Office on Sep. 21, 2022, the entire content of which is incorporated herein by reference.

### BACKGROUND

### 1. Field

Aspects of some embodiments of the present disclosure relate to a display device.

### 2. Description of the Related Art

A light emitting display device is a self-emissive display device that displays images by emitting light from a light emitting diode LED.

Such a light emitting display device may be utilized in various electronic devices, and a head-mounted display device that displays images by placing the same directly in front of the user's eyes may be used to provide users with a three-dimensional effect or immersion.

As a polarizer is used in the head-mounted display device, there may be a drawback of low optical efficiency of the display device.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a display device having a relatively large-sized light emitting element or anode. Aspects of some embodiments, relate to a display device for a head-mounted display device.

Aspects of some embodiments include a display device having a relatively large-sized light emitting element or anode.

A display device according to some embodiments includes: a substrate; a pixel circuit driving portion on the substrate; an organic layer that covers the pixel circuit driving portion; a light emitting element on the organic layer and includes an anode; and a separator including a reverse tapered side on the organic layer, wherein a width of a bottom surface of the separator is the same as a space between adjacent anodes.

According to some embodiments, the organic layer may include a contact hole connecting the pixel circuit driving portion and the anode, and the light emitting element may overlap the contact hole on a plane (or in a plan view).

According to some embodiments, the separator and the contact hole may not overlap on a plane (or in a plan view).

According to some embodiments, the anode may have a step at the periphery of the contact hole.

According to some embodiments, the display device may further include an inorganic insulation layer only on the reverse tapered side of the separator.

According to some embodiments, the light emitting element may further include a middle layer on the anode and includes an emission layer, and a cathode, wherein the middle layer may not be on the reverse tapered side of the separator and is separated based on the separator, and the cathode may also be on the reverse tapered side of the separator and may be connected to each other on both sides of the separator.

According to some embodiments, a portion of the middle layer may be on an upper surface of the separator.

According to some embodiments, the display device may further include a capping layer on the cathode, where the capping layer may not be on the reverse tapered side of the separator and may be separated based on the separator.

According to some embodiments, the anode may also be between the reverse tapered side of the separator and the inorganic insulation layer.

According to some embodiments, the light emitting element may further include a middle layer on the anode and including an emission layer, and a cathode, the middle layer may not be on the reverse tapered side of the separator and may be separated based on the separator, and the cathode may also be on the reverse tapered side of the separator and connected to each other on both sides of the separator.

According to some embodiments, a portion of the middle layer may be on an upper surface of the separator.

According to some embodiments, the display device may further include a top protective layer that is between the anode on the reverse tapered side of the separator and the inorganic insulation layer.

According to some embodiments, the upper protective layer may have a lower height than the anode and the inorganic insulation layer on the reverse tapered side of the separator.

A display device according to some embodiments includes: a substrate; a pixel circuit driving portion that is on the substrate; an organic layer that covers the pixel circuit driving portion; an anode on the organic layer; a pixel definition layer that is on the organic layer, and covers a part of the anode; and a separator that is on the pixel definition layer, and includes a reverse tapered side, wherein the organic layer comprises a contact hole connecting the pixel circuit driving portion and the anode, and the pixel definition layer and the separator do not overlap the contact hole on a plane.

According to some embodiments, the display device may further include a middle layer that is on the anode and includes an emission layer, and a cathode, the middle layer may be on the pixel definition layer, but not on the reverse tapered side of the separator and thus may be separated based on the separator, and the cathode may be above the pixel definition layer and also on the reverse tapered side of the separator, and thus connected to each other on both sides of the separator.

According to some embodiments, a portion of the middle layer may be on an upper surface of the separator.

A display device according to some embodiments includes: a substrate; a first pixel circuit driving portion that is on the substrate; an organic layer that covers the first pixel circuit driving portion; and a first anode and a second anode on the organic layer, the first anode connected with the first pixel driving portion and the second anode adjacent to the first anode, the organic layer includes a contact hole that connects the first pixel circuit driving portion and the first anode, and the first anode and the second anode overlap each other on the contact hole on a plane.

According to some embodiments, the display device may further include a first passivation layer and a second passivation layer respectively between the organic layer and the first anode and between the organic layer and the second anode, wherein a tip may be formed at an end of the second passivation layer, and the end of the second passivation layer may overlap the contact hole on a plane.

According to some embodiments, the display device may further include: a pixel definition layer that is on the organic layer, and covers the first anode and a part of the second anode; and a separator that is on the pixel definition layer, and has a reverse tapered side, and the pixel definition layer and the separator may overlap the contact hole on a plane.

According to some embodiments, the anode or light emitting element may be formed to be large by overlapping an adjacent anode in a contact portion or forming an anode and an emission layer overlapping in a contact portion. In addition, display luminance may be increased through a large-sized light emitting element. In addition, the display device according to some embodiments may be used for the head-mounted display device such that the head-mounted display device can display images with a relatively high luminance.

### BRIEF DESCRIPTION OF THE DRAWINGS

FIG. 1 is a schematic cross-sectional view of a head-mounted display device according to some embodiments.

FIG. 2 is a top plan view of a display device according to some embodiments.

FIG. 3 is a cross-sectional view of the display device of FIG. 2 according to some embodiments.

FIG. 4 shows a manufacturing process of the display device of FIG. 2 according to some embodiments.

FIG. 5 is an enlarged cross-sectional view of a part of the display device of FIG. 2 according to some embodiments.

FIG. 6 is a cross-sectional view of a manufacturing process of a display device according to some embodiments.

FIG. 7 is an enlarged cross-sectional view of a part of the display device of FIG. 6 according to some embodiments.

FIG. 8 is a cross-sectional view of a manufacturing process of a display device according to some embodiments.

FIG. 9 is an enlarged cross-sectional view of a part of the display device of FIG. 8 according to some embodiments.

FIG. 10 is a top plan view of a display device according to some embodiments.

FIG. 11 is a cross-sectional view of the display device of FIG. 10 according to some embodiments.

FIG. 12 shows a manufacturing process of the display device of FIG. 10 according to some embodiments.

FIG. 13 is a top plan view of a display device according to some embodiments.

FIG. 14 is a cross-sectional view of FIG. 13 according to some embodiments.

FIG. 15 shows a manufacturing process of the display device of FIG. 13 according to some embodiments.

FIG. 16 is an enlarged cross-sectional view of a part of the display device of FIG. 13 according to some embodiments.

FIG. 17 is a drawing for comparing and describing a comparative example and embodiments.

FIG. 18 is a schematic entire cross-sectional view of a display device according to some embodiments.

### DETAILED DESCRIPTION

Hereinafter, with reference to accompanying drawings, aspects of some embodiments of the present disclosure will be described in more detail and thus a person of an ordinary skill can relatively easily practice them in the technical field to which the present invention belongs. The present disclosure may be embodied in many different forms and is not limited to the embodiments described herein.

In order to more clearly explain embodiments according to the present invention, parts irrelevant to the description have been omitted, and the same reference numerals should be attached to the same or similar constituent elements throughout the specification.

In addition, because the size and thickness of each component shown in the drawing is arbitrarily shown for convenience of explanation, the present disclosure is not necessarily limited to the drawing. In the drawings, the thickness of layers, films, panels, regions, etc., are exaggerated for clarity. In addition, in the drawing, the thickness of some layers and regions is exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to be positioned above or below the target element, and will not necessarily be understood to be positioned “at an upper side” based on an opposite to gravity direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top or in a plan view, and the phrase “on a cross-section” means viewing a cross-section formed by vertically cutting a target portion from the side.

Throughout the specification, “connected” does not mean only when two or more constituent elements are directly connected, but also when two or more constituent elements are indirectly connected through another constituent element, or when physically connected or electrically connected, and it may include a case in which substantially integral parts are connected to each other although they are referred to by different names according to positions or functions.

In addition, in the entire specification, when parts such as wiring, layers, films, regions, plates, and constituent elements are “extended in the first direction or second direction”, this not mean only a straight line shape extending in the corresponding direction, but means a structure that extends overall along the first or second direction, including a structure that is bent in one part, has a zigzag structure, or extends including a curved line structure.

In addition, electronic devices (for example, mobile phone, TV, monitor, laptop computer, etc.) including display devices and display panels described in the specification or electronic devices including the display device and display panel manufactured by the manufacturing method described in the specification, are not excluded from the scope of rights of this specification.

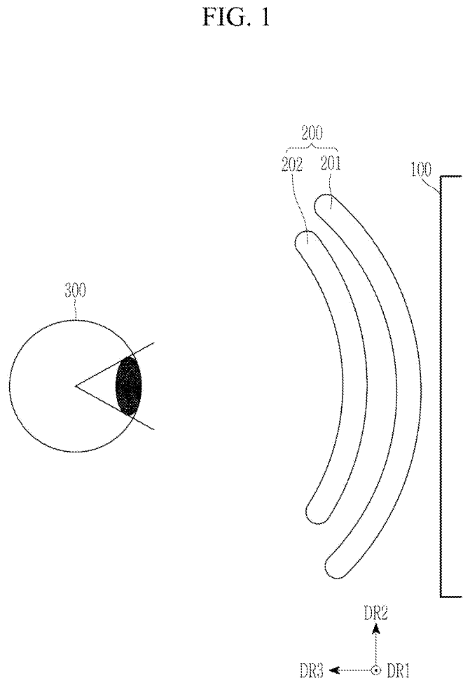

A display device according to the present disclosure may be included in various electronic devices, and a schematic structure of a head-mounted display device, which is embodiments of various electronic devices will be described with reference to FIG. 1.

FIG. 1 is a schematic cross-sectional view of a head-mounted display device according to some embodiments.

A head-mounted display device according to some embodiments includes a display device 100 and an optical system 200 positioned in front of the display device 100.

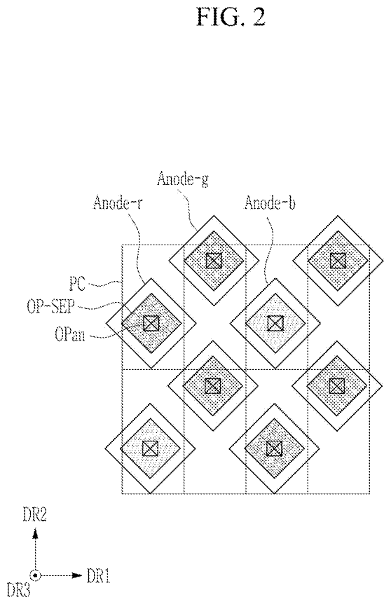

Here, the display device 100 may be one of display devices to be described in more detail with reference to FIG. 2 to FIG. 18. In addition, the optical system 200 is positioned between the display device 100 and the user's eye 300 to make light emitted from the display device 100 look relatively wider, thereby improving immersion or a three-dimensional effect as perceived by users or viewers.

The optical system 200 includes two curved lenses 210 and 220 (hereinafter referred to as a pancake lens), and an optical film may be formed on at least one surface of each curved lens.

The optical system 200 according to some embodiments will now be described in more detail.

A first phase difference plate may be positioned on a side of the display device 100 (hereinafter referred to as an inner side in the opposite direction of the third direction DR3) of the first curved lens 210 (hereinafter referred to as a first pancake lens) positioned adjacent to the display device 100, and a beam splitter may be formed on an outer side (third direction DR3 side). Here, the first phase difference plate is a λ/4 plate, and it may be possible to change linear polarization to one polarization or change one polarization to linear polarization by providing a phase difference of λ/4 with respect to the delay axis. The beam splitter may transmit half of the incident light and reflect the other half, and may reflect and transmit light regardless of the polarization characteristics of the light.

A second phase difference plate is formed on an inner side (opposite direction of the third direction DR3) of the second curved lens 220 (hereinafter referred to as a second pancake lens) positioned adjacent to the user's eye 300, and a reflective polarizer is formed on an outer side (the third direction DR3 side). Here, the second phase difference plate may also be a λ/4 plate, and the reflective polarizer has a reflection axis, and the polarization of the reflection axis is reflected, and the polarization in the vertical direction may be transmitted. The reflective polarizer may have a wire grid structure in which a plurality of metal lines having a fine width are arranged in one direction, reflect light parallel to the direction of the metal line arrangement, and transmit light perpendicular thereto. In this case, the interval between the plurality of metal lines may be narrower than the wavelength of visible rays.

The first curved lens 201 and the second curved lens 202 included in the optical system 200 may be formed of an optically isotropic material, such as glass or polymethyl methacrylate (PMMA). In addition, curved surfaces of the first curved lens 201 and the second curved lens 202 may be spherical or aspherical.

The display device 100 may be used for a head-mounted display device like the structure of FIG. 1, or it may be used for an electronic device (e.g., a mobile phone, a TV, a monitor, a laptop computer, etc.).

Hereinafter, the structure of the display device 100 according to various embodiments will be reviewed, and a display device 100 according to some embodiments will be described in more detail with reference to FIG. 2 to FIG. 5.

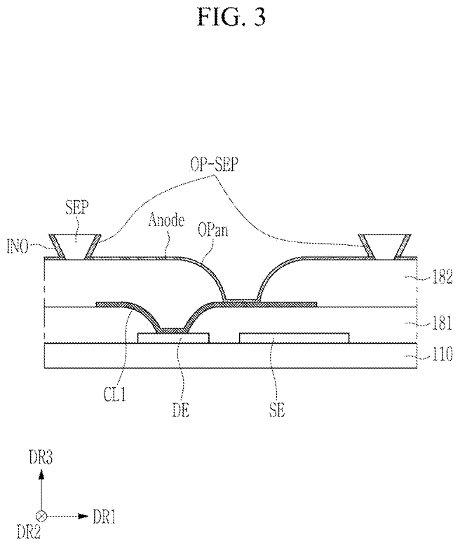

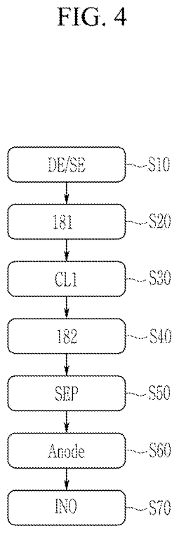

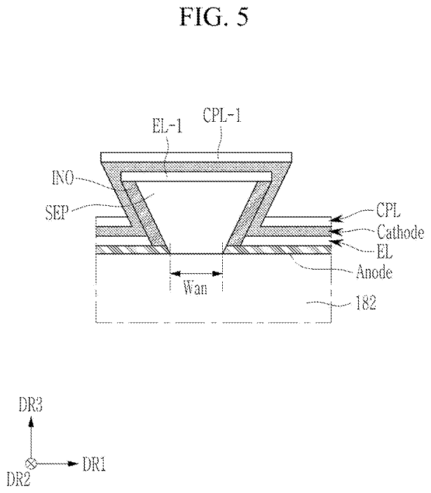

FIG. 2 is a top plan view of a display device according to some embodiments, FIG. 3 is a cross-sectional view of the display device according to the embodiments of FIG. 2, FIG. 4 shows a manufacturing process of the display device according to the embodiments of FIG. 2, and FIG. 5 is an enlarged cross-sectional view of a part of the display device according to the embodiments of FIG. 2.

First, a planar structure of FIG. 2 will be described in more detail.

FIG. 2 schematically illustrates a pixel included in the display device.

Each pixel includes a single pixel driving circuit portion PC and a light emitting element that includes a single anode Anode-r, Anode-g, or Anode-b electrically connected with the pixel driving circuit portion PC. In FIG. 2, the pixel driving circuit portion PC is simplified and shown as a square, and a driving transistor that generates an output current with the anodes Anode-r, Anode-g, and Anode-b of the light-emitting element is included.

The output current of the driving transistor included in the pixel driving circuit portion PC is transmitted to the anodes Anode-r, Anode-g, and Anode-b through a contact hole OPan. The light emitting element further includes an emission layer and a cathode, and the cathode may be formed over the entire display area of the display device.

In the display device according to the embodiments of FIG. 2, a separator SEP (refer to FIG. 3) is positioned above pixel driving circuit portion PC, while partially overlapping the anodes Anode-r, Anode-g, and Anode-b. The separator SEP serves to separate adjacent anodes, and an opening OP-SEP of the separator SEP overlapping with the anodes Anode-r, Anode-g, and Anode-b is formed. In FIG. 2, only the opening OP-SEP of the separator SEP is shown, and all parts of the separator SEP other than the opening OP-SEP may be separator SEP.

Hereinafter, a cross-sectional structure of the display device according to the embodiments of FIG. 2 will be described with reference to FIG. 3.

In FIG. 3, only one anode Anode of the three anodes Anode-r, Anode-g, and Anode-b of FIG. 2 is mainly shown, and a structure of the pixel driving circuit portion PC is also schematically shown.

Referring to FIG. 3, a structure between the structure between a first data conductive layer including connection electrodes SE and DE that may be connected to the first region and second region of the transistor positioned on a substrate 110 may be omitted. The structure of this portion may include at least one transistor (driving transistor), and the stacked structure may vary.

The substrate 110 may include a material that has a rigid characteristic such as glass and does not bend, or may include a flexible material that can be bent, such as plastic or polyimide. In the case of a flexible substrate, a double-layered structure of polyimide and a barrier layer formed of an inorganic insulating material thereon may be repeatedly formed.

A transistor including a semiconductor layer and a gate electrode may be formed on the substrate 110, and a capacitor including two overlapping electrodes may also be formed. A plurality of insulation layers may be included between a semiconductor layer and an electrode for insulation.

A channel is located in a portion of the semiconductor layer included in the semiconductor, overlapping a gate electrode, and a first region and a second region are located on both sides of the channel. On the substrate 110, the first data conductive layer including the connection electrodes SE and DE that may be connected to the first region and the second region of the transistor may be arranged. The first data conductive layer may include a metal such as aluminum (Al), copper (Cu), molybdenum (Mo), titanium (Ti), and the like or a metal alloy thereof, and may be formed of a single layer or multiple layers.

A first organic layer 181 may be located on the first data conductive layer. The first organic layer 181 may be an organic insulator including an organic material, and the organic material may include at least one material selected from a group consisting of polyimide, polyamide, acryl resin, benzocyclobutene, and phenol resin.

A second data conductive layer including an anode connection line CL1 may be located on the first organic layer 181. The second data conductive layer may include a data line or a first voltage line (driving voltage line). The second data conductive layer may include a metal such as aluminum (Al), copper (Cu), molybdenum (Mo), titanium (Ti), and the like or a metal alloy thereof, and may be formed of a single layer or multiple layers. The anode connection line CL1 is connected to the connection electrode DE through an opening located on the first organic layer 181.

A second organic layer 182 is located on the second data conductive layer, and the second organic layer 182 may be an organic insulator and may include at least one material selected from a group consisting of polyimide, polyamide, acryl resin, benzocyclobutene and phenol resin.

The anode Anode of the light emitting element is formed on the second organic layer 182. The contact hole OPan is formed in the second organic layer 182, and the anode Anode and the anode connection line CL1 are connected through the contact hole OPan. As a result, the anode Anode receives the output current of the transistor through the anode connection line CL1 and the connection electrode DE.

The separator SEP of which a bottom surface is located between adjacent anodes Anodes is formed on the second organic layer 182. The separator SEP is formed of an organic material, and according to some embodiments, it may be formed of a transparent organic material or a black color to prevent or reduce instances of external light being reflected. The separator SEP has a wider upper surface than the bottom surface, and a reverse tapered structure is formed on a side surface thereof. Due to the reverse tapered side, at least one layer may have a structure that is separated from each other based on the separator SEP. Due to the reverse tapered structure of the separator SEP, an organic material is disconnected without being connected, and the cathode is positioned on the side of the separator SEP by using damage free sputter equipment with a relatively low incident angle, and may have a structure that goes over the separator SEP.

Referring to FIG. 2 and FIG. 3, because the upper surface of the separator SEP is relatively wide, a portion of the planar separator SEP may have a structure overlapping with a part of the anode. A space between adjacent separator SEPs forms the opening OP-SEP of the separator SEP.

An inorganic insulation layer INO is formed on the reverse tapered side of the separator SEP. The inorganic insulation layer INO may include an inorganic material such as a silicon oxide (SiOₓ), a silicon nitride (SiNₓ), or a silicon oxynitride (SiOₓN_{y}). When the inorganic insulation layer INO is laminated using chemical vapor deposition (CVD), which enables lamination even if there is a relative step difference, the inorganic lay can be laminated on the reverse tapered side. In the inorganic insulation layer INO formed in this way, an inorganic insulating material is formed to prevent or reduce instances of current being concentrated during light emission while the edge portion of the anode Anode and light emitting element is formed narrowly. That is, the structure of the inorganic insulation layer INO and the separator SEP may be combined to serve as a pixel defining layer PDL positioned around the general anode.

According to some embodiments, referring to FIG. 5, a middle layer EL including an emission layer, a cathode Cathode, and a capping layer CPL may be further included on the anode Anode and the separator SEP. Further details of the structure will be described with reference to FIG. 5.

The structure shown in FIG. 2 and FIG. 3 may be manufactured through a manufacturing method of FIG. 4.

Referring to FIG. 4, the first data conductive layer including the connection electrodes SE and DE that can be connected to the first region and second region of the transistor is formed on the substrate 110 (S10). The first data conductive layer may include a metal such as aluminum (Al), copper (Cu), molybdenum (Mo), titanium (Ti), and the like or a metal alloy thereof, and may be formed of a single layer or multiple layers.

Thereafter, a first organic layer 181 is laminated on the first data conductive layer (S20). The first organic layer 181 may include at least one material selected from a group consisting of polyimide, polyamide, acryl resin, benzocyclobutene, and phenol resin. In this case, an opening exposing a portion of the connection electrode DE is formed in the first organic layer 181 such that it can be connected to an anode connection line CL1 in a subsequent process.

After that, a second data conductive layer including the anode connection line CL1 is formed on the first organic layer 181 (S30). The second data conductive layer may include a metal such as aluminum (Al), copper (Cu), molybdenum (Mo), titanium (Ti), and the like or a metal alloy thereof, and may be formed of a single layer or multiple layers. The anode connection line CL1 is connected to the connection electrode DE through an opening formed in the first organic layer 181.

After that, a second organic layer 182 is laminated on the second data conductive layer (S40). The second organic layer 182 may include at least one material selected from a group consisting of polyimide, polyamide, acryl resin, benzocyclobutene, and phenol resin. In this case, a contact hole OPan exposing a part of the anode connection line CL1 is formed in the second organic layer 182 and thus it may be connected to the anode Anode in a subsequent process.

After that, the separator SEP is formed with an organic material on the second organic layer 182 (S50). The separator SEP has a wider upper surface than the bottom surface, and a reverse tapered side surface. Due to the reverse tapered side, at least one layer may have a structure that is separated from each other based on the separator SEP. A space between adjacent separator SEPs forms the opening OP-SEP of the separator SEPs.

After that, the anode Anode is formed on the second organic layer 182 and in a part where the separator SEP is not located (S60). The process of forming the anode Anode (S60) will now be described in more detail.

A conductive material for the anode is laminated over the entire region where the second organic layer 182 and separator SEP are located. In this case, because the side of the separator SEP has a reverse tapered structure, the conductive material for the anode may not be laminated on side surfaces of the separator SEP. In this case, the conductive material for the anode is located on an upper surface of the separator SEP, and the conductive material for the anode is also located on the second organic layer 182.

After that, the conductive material for the anode of the second organic layer 182 is protected using a photo-resist and a mask, and the conductive material for the anode on the upper surface of the separator SEP is exposed to be etched, and then the photo-resist pattern is used as a mask to etch the conductive material for the anode on the upper surface of the separator SEP to thereby complete the anode Anode.

After that, an inorganic insulation layer INO is formed on the reverse tapered side of the separator SEP (S70). Here, when the inorganic insulation layer INO is laminated using chemical vapor deposition (CVD), which enables lamination even if there is a relative step difference, and after the lamination, the inorganic insulation layer INO located on the anode Anode and on the separator SEP is etched using a mask. Then, the inorganic insulation layer INO may be positioned only on the reverse tapered side of the separator SEP. As a result, the structure of inorganic insulation layer INO and the separator SEP may be combined to serve as a pixel defining layer PDL positioned around a general anode.

According to some embodiments, the second data conductive layer including the anode connection line CL1 and the second organic layer 182 may be omitted.

In FIG. 2 to FIG. 4, only the separator SEP and the anode Anode are illustrated, and the light emitting element further includes a middle layer EL including an emission layer and a cathode Cathode in addition to the anode Anode. The overall structure of this light emitting element will now be described in more detail with reference to FIG. 5.

FIG. 5 is an enlarged view of a structure above the second organic layer 182, and a separator SEP and a light emitting element are formed on the second organic layer 182 and a capping layer CPL is located thereon.

For example, the separator SEP and the anode Anode of the light emitting element are formed on the second organic layer 182, and the inorganic insulation layer INO is located on the reverse tapered side of the separator SEP.

Referring to FIG. 5, it can be confirmed that a gap between adjacent anodes Anodes is the same as a width Wan of the bottom surface of the separator SEP. Due to a structure that the bottom surface of the separator SEP is narrower than the upper surface and thus a distance between adjacent anodes Anodes can be narrowed, a size of the light emitting element can be formed relatively large and the luminance of the display device can be relatively improved.

In addition, a middle layer EL including an emission layer is located on the anode Anode, and a part of the middle layer, EL-1, is located on the upper surface of the separator SEP. That is, the middle layer is not positioned on the reverse tapered side of the separator SEP, and thus the middle layer on both sides is separated based on the separator SEP. The part EL-1 of the middle layer located on the upper surface of the separator SEP may not be located on the side of the separator SEP. Here, the emission layer may include an emission layer displaying a white color.

The middle layer EL including an emission layer and located on the anode Anode may be specifically divided into a first functional layer, an emission layer, and a second functional layer. The first functional layer is located between the anode and the emission layer, and the second functional layer is located above the emission layer. The first functional layer located below the emission layer may include a hole injection layer and/or hole transport layer, and the second functional layer located above the emission layer may include an electron transport layer and/or electron injection layer. Here, the first functional layer and the second functional layer may contact each other in the vicinity where the emission layer is not positioned.

According to some embodiments, the part EL-1 of the middle layer positioned on an upper surface of the separator SEP may not include an emission layer.

The cathode Cathode is positioned on the middle layer, and the cathode may have a structure in which it is also located on a side of the separator SEP by using damage free sputter equipment with a relatively low incident angle, and extends over the separator SEP and connected at both sides of the separator SEP.

The capping layers CPL and CPL-1 are located on the cathode Cathode, and the capping layers are separated based on the separator SEP because they are not located on the reverse tapered side of the separator SEP. In addition, the capping layer CPL-1 is located on the upper surface of the separator SEP, and the capping layer CPL is located on a part that does not overlap with the separator SEP.

An encapsulation layer may be located on the capping layers CPL and CPL-1, and when the light emitting element is a light emitting element displaying white color, red, green, and blue color filters may be additionally formed.

Hereinabove, embodiments in which an anode Anode is not formed on the side of the separator SEP have been described.

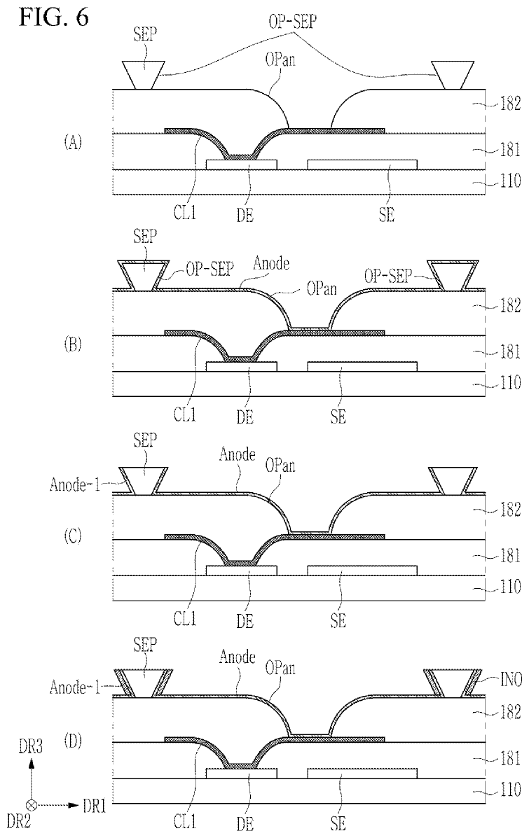

Hereinafter, embodiments in which an anode Anode-1 is formed at a side of a separator SEP will be described in more detail with reference to FIG. 6 to FIG. 9.

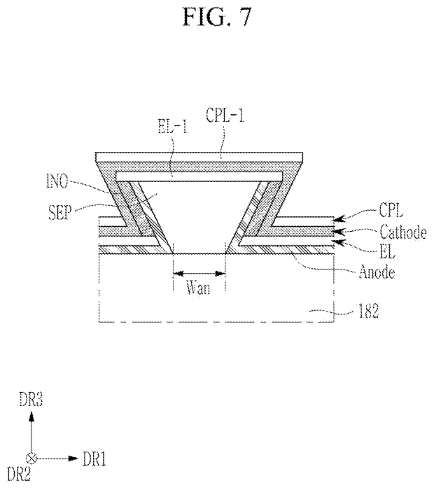

First, embodiments of FIG. 6 and FIG. 7 will be described in more detail.

FIG. 6 is a cross-sectional view of a manufacturing process of a display device according to some embodiments, and FIG. 7 is an enlarged cross-sectional view of a part of the display device according to some embodiments as illustrated in FIG. 6.

First, a manufacturing process will be described in more detail with reference to FIG. 6.

In FIG. 6(A), a state in which a separator SEP is formed on a second organic layer 182 is illustrated.

Next, as shown in FIG. 6(B), a conductive material for anode Anode′ is laminated over the entire region, and particularly, the conductive material for anode Anode′ is laminated on side and upper surfaces of the separator SEP. In order to laminate the conductive material for the anode Anode′ on the side of the separator SEP, the conductive material for the anode Anode′ can be laminated by adjusting a sputtering angle.

Next, as shown in FIG. 6(C), the conductive material for the anode Anode′ located on the upper surface of the separator SEP is removed using a mask and photo resist. As a result, an anode Anode may include a part Anode-1 that is extended and located on the side of the separator SEP.

Next, as shown in FIG. 6(D), an inorganic insulation layer INO is formed on the reverse tapered side of the separator SEP. Here, the inorganic insulation layer INO is laminated using the chemical vapor deposition method (CVD), which can be laminated even through there is a relative step difference, and after lamination, the inorganic insulation layer INO located on the anode Anode and on the separator SEP may be etched using a mask.

In the embodiments formed in this way, the anode Anode-1 and the inorganic insulation layer INO are located on the side of the separator SEP.

Hereinafter, the entire structure of a light emitting element according to the embodiments of FIG. 6 will be described in more detail with reference to FIG. 7.

As opposed to the embodiments shown with respect to FIG. 5, in the embodiments of FIG. 7, the anode Anode-1 is located on the reverse tapered side of the separator SEP and the inorganic insulation layer INO is located on the anode Anode-1.

The structure other than the above-stated structure is the same as the structure shown in FIG. 5, and two adjacent anodes Anodes are separated by the separator SEP and the separator SEP may serve as a pixel defining layer PDL arranged around the anode. On the other hand, the inorganic insulation layer INO may serve to prevent or reduce instances of the part Anode-1 located on the side of the separator SEP among the anodes Anode, a middle layer of the light emitting element, and a cathode being electrically directly connected.

Referring to FIG. 7, it can be determined that a gap between adjacent anodes Anodes is the same as a width Wan of a bottom surface of the separator SEP. Due to a structure that the bottom surface of the separator SEP is narrower than the upper surface and thus a distance between adjacent anodes Anodes can be narrowed, a size of the light emitting element can be formed relatively large and the luminance of the display device can be improved.

As shown in 6(D), in the embodiments of FIG. 6 and FIG. 7, when the inorganic insulation layer INO is laminated, the anode Anode may be damaged, and thus hereinafter, embodiments further including a top protective layer TPL to protect the anode will be described in more detail.

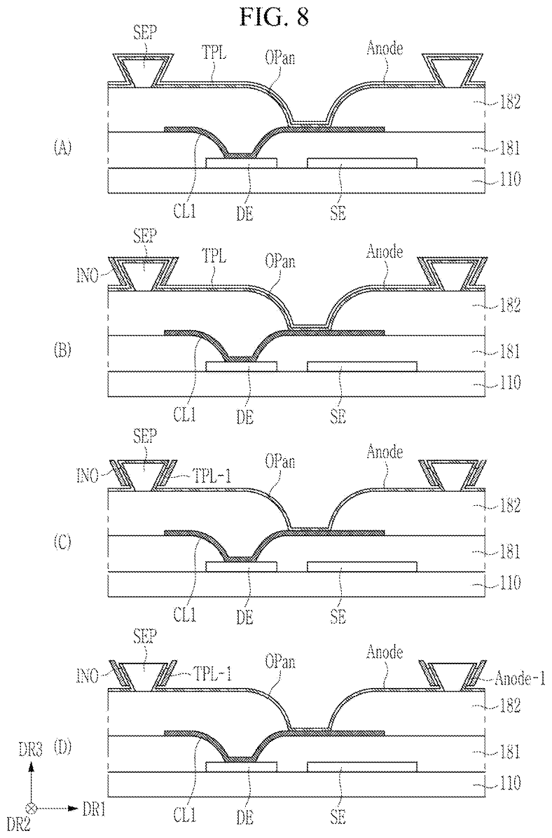

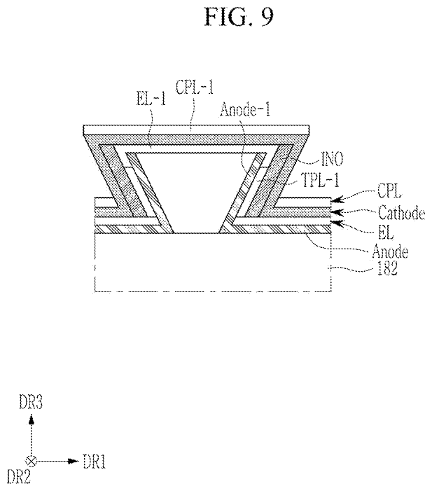

FIG. 8 is a cross-sectional view of a manufacturing process of a display device according to some embodiments, and FIG. 9 is an enlarged cross-sectional view of a part of the display device according to the embodiments of FIG. 8.

In embodiments of FIG. 8 and FIG. 9, a top protective layer TPL is further included on an anode Anode.

FIG. 8(A) illustrates stages after the overall lamination of the conductive material for the anode Anode′.

Referring to FIG. 8(A), the top protective layer TPL is formed above and in the entire the conductive material for the anode Anode′. That is, the top protective layer TPL is also formed on a side of the separator SEP.

After that, as shown in FIG. 8(B), the inorganic insulation layer INO is formed on the reverse tapered side of the separator SEP and on the top protective layer TPL. The inorganic insulation layer INO is laminated using chemical vapor deposition (CVD) even if there is a relative step difference, and after the lamination, the inorganic insulation layer INO positioned on the anode Anode and on the separator SEP can be etched using a mask. When the inorganic insulation layer INO is laminated, the top protective layer TPL is formed on a conductive material for anode Anode′, and thus the conductive material for anode Anode′ may have the merit of not being damaged.

After that, as shown in FIG. 8(C), the top protective layer TPL is removed by wet etching without a mask. The remaining top protective layer TPL is removed except for a portion TPL-1 of the top protective layer TPL covered with the inorganic insulation layer INO on the reverse tapered side of the result separator SEP. Referring to FIG. 8(C), since the top protective layer TPL is removed by wet etching, a structure in which the top protective layer TPL-1 is not located may be formed in an upper portion of the reverse tapered side of the separator SEP. That is, the portion TPL-1 of the top protective layer TPL may have a height lower than that of the inorganic insulation layer INO located on the reverse tapered side of the separator SEP.

After that, as shown in FIG. 8(D), the conductive material Anode′ for the anode that is laminated over the entire region and located on the upper surface of the separator SEP is removed using a mask and photo resist. As a result, the anode Anode may include a portion Anode-1 that is extended and located on the side of the separator SEP. Here, the portion TPL-1 of the top protective layer TPL may have a height lower than that of the anode Anode-1 located on the reverse tapered side of the separator SEP and the inorganic insulation layer INO.

The overall structure of the light emitting element manufactured by the above-described manufacturing method will be described with reference to FIG. 9.

Unlike the structure shown in FIG. 5, in the structure shown in FIG. 9, the anode Anode-1 is located on the reverse tapered side of the separator SEP, and not as in the structure shown in FIG. 7, the top protective layer TPL-1 is located between the anode Anode-1 and the inorganic insulation layer INO on the reverse tapered side.

In the structure of FIG. 9, two adjacent anodes Anodes are separated by the separator SEP, and the separator SEP may serve as a pixel definition layer PDL arranged around the anode. On the other hand, the anode Anode-1 and the inorganic insulation layer INO on the reverse tapered side may serve to prevent or reduce instances of the portion Anode-1 located on the side of the separator SEP among the anodes Anode being electrically directly connected to a middle layer a cathode of the light emitting element.

Referring to FIG. 9, it can be confirmed that the smallest value among the distances between adjacent anodes Anodes is equal to the width Wan of the bottom surface of the separator SEP. Due to a structure in which the bottom surface of the separator SEP is narrower than the top surface and thus the distance between adjacent anodes Anodes can be reduced, the size of the light emitting element can be formed relatively large and the luminance of the display device can be improved.

In FIG. 9, the middle layer EL and/or the cathode Cathode may fill a portion where the top protective layer TPL-1 is not located between the anode Anode-1 and the inorganic insulation layer INO at the reverse tapered side. That is, a portion where the top protective layer TPL-1 is over-etched during wet etching may be filled by the middle layer EL and/or the cathode Cathode located thereon.

In the embodiments of FIG. 2 to FIG. 9, in order to form a large area/size of the light emitting element or anode Anode, the contact hole OPan connected to the anode Anode is formed at a position overlapping the emission layer of the light emitting element on a plane (or in a plan view), and thus the size of the area where the light emitting element is not located can be reduced.

In addition, a minimum distance between adjacent anodes Anodes is formed equal to the width Wan of the bottom surface of the separator SEP, and since the bottom surface of the separator SEP is narrower than the upper surface, the distance between adjacent anodes Anodes. In addition, the anode Anode is formed in a rhombus shape to reduce the distance between adjacent anodes Anode as much as possible.

Due to these characteristics, the size of the light emitting element can be formed relatively large and the luminance of the display device can be improved.

As in the above embodiments, although only one of (i) overlapping the contact hole OPan with the emission layer on a plane (or in a plan view) and (ii) minimizing or reducing the distance between adjacent anodes Anodes is applied, the area/size of the light emitting element or anode can be increased, thereby relatively increasing the luminance of the display device.

Therefore, hereinafter embodiments that apply only one of the above two will be described.

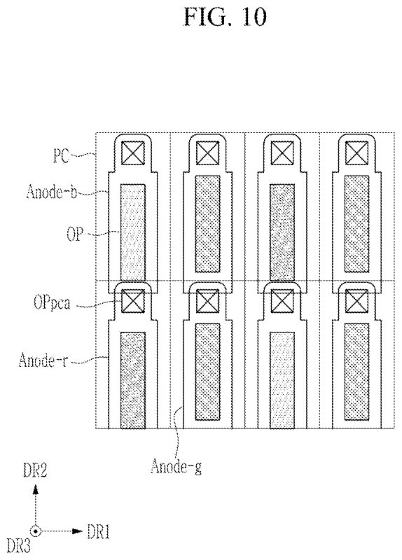

First, referring to FIG. 10 to FIG. 12, embodiments having a structure in which two adjacent anodes Anodes partially overlap in the vicinity of a contact hole to minimize the distance between adjacent anodes Anodes will be described.

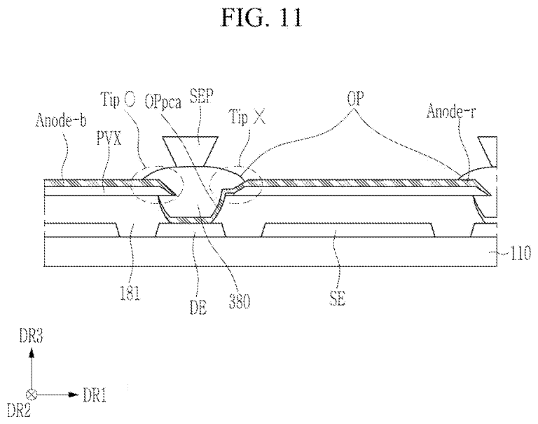

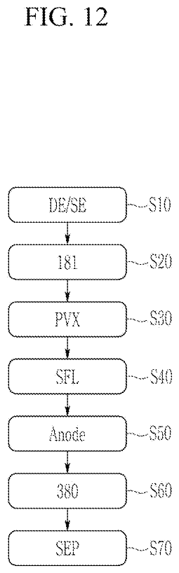

FIG. 10 is a top plan view of a display device according to some embodiments, FIG. 11 is a cross-sectional view of the display device according to the embodiments of FIG. 10, and FIG. 12 shows a manufacturing process of the display device according to the embodiments of FIG. 10.

First, a top plan structure shown in FIG. 10 will be described in more detail.

Unlike the rhombus shape shown in FIG. 2, a light emitting element of FIG. 10 may have a rectangle shape.

As shown in FIG. 2, FIG. 10 schematically illustrates a pixel included in the display device, and in FIG. 10, a pixel driving circuit portion PC, anodes Anode-r, Anode-g, and Anode-b, an opening OP of a pixel definition layer 380 (refer to FIG. 11), and a contact hole OPpca that connects the pixel driving circuit portion PC and one of the anodes Anode-r, Anode-g, and Anode-b are illustrated. The contact hole OPpca does not overlap the opening OP of the pixel definition layer 380, and an emission layer is located in the opening OP of the pixel definition layer 380 and a light emitting element is also located in the opening OP. Therefore, the contact hole OPpca and the light emitting element have a non-overlapping structure.

In the embodiments of FIG. 10, almost each of the anodes Anode-r, Anode-g, and Anode-b is arranged while overlapping the pixel driving circuit portion PC connected thereto. A portion of the anodes Anode-r, Anode-g, and Anode-b is exposed through the opening OP of the pixel definition layer 380, and the portion may be a portion corresponding to a light emitting element.

The anodes Anode-r, Anode-g, and Anode-b are extended in a second direction, and have a structure in which the anodes Anode-r, Anode-g, and Anode-b overlap adjacent anodes Anode-r, Anode-g, and Anode-b in the second direction on a plane on the contact hole OPpca, and thus the anodes Anode-r, Anode-g, and Anode-b may have the maximum length in the second direction. The structure in which two adjacent anodes overlap on a plane will be described through the cross-sectional structure shown in FIG. 11.

Referring to FIG. 11, only connection electrodes SE and DE connected with a first region and a second region of a transistor are illustrated, and the connection electrode DE is connected with an anode Anode-r (hereinafter also referred to as a present-stage anode) arranged above by a contact hole OPpca formed in a first organic layer 181.

In the embodiments of FIG. 11, a passivation layer PVX is located on the first organic layer 181, and the passivation layer PVX may include an inorganic material such as a silicon oxide (SiOₓ), a silicon nitride (SiNₓ), or a silicon oxynitride (SiOₓN_{y}). The passivation layer PVX is separated into both sides on the contact hole OPpca, and the passivation layer PVX on one side has a structure in which a tip is formed, but no tip is formed on the opposite side.

The anodes Anode-r and Anode-b are located on the passivation layer PVX, and a present-stage anode Anode-r (hereinafter referred to as a first anode) connected to the pixel driving circuit portion PC through the contact hole OPpca is connected to the pixel driving circuit portion PC through the passivation layer PVX (hereinafter also referred to as a first passivation layer) where no top Tip is formed and the contact hole OPpca. On the other hand, the anode (Anode-b; hereinafter referred to as the second anode) of an adjacent pixel is positioned on the passivation layer (PVX; hereinafter referred to as the second passivation layer) on which the tip is formed, and the pixel passes through the contact hole OPpca. It is electrically separated from the driving circuit portion PC. Anodes Anode-b of adjacent pixels overlap the first anode Anode-r on a plane around the contact hole OPpca. An end of the passivation layer PVX (i.e., a second passivation layer) on which the tip is formed overlaps the contact hole OPpca on a plane. A structure having a tip as described above may be formed using a sacrificial layer, and such a structure will be described in detail with reference to FIG. 12.

Referring to FIG. 11, the display device additionally includes a pixel definition layer 380 covering the contact hole OPpca and a separator SEP located on the pixel definition layer 380. Here, the contact hole OPpca may overlap the pixel definition layer 380 and the separator SEP on a plane. The pixel definition layer 380 is located only around the contact hole OPpca and includes an opening OP exposing most of the anodes Anode-r and Anode-b. The separator SEP is located only on the pixel definition layer 380, and an upper surface of the separator SEP is wider than a bottom surface, and side surfaces are formed in a reverse tapered structure. Due to the reverse tapered side, at least one layer may have a structure that is separated based on the separator SEP.

The structure shown in FIG. 10 and FIG. 11 may be manufactured by using a manufacturing method of FIG. 12.

Referring to FIG. 12, a first data conductive layer including the connection electrodes SE and DE that can be connected with the first region and the second region of the transistor is formed on a substrate 110 (S10). The first data conductive layer may include a metal such as aluminum (Al), copper (Cu), molybdenum (Mo), titanium (Ti), and the like or a metal alloy thereof, and may be formed of a single layer or multiple layers.

After that, a first organic layer 181 is laminated on the first data conductive layer (S20). The first organic layer 181 may include at least one material selected from a group consisting of polyimide, polyamide, acryl resin, benzocyclobutene, and phenol resin. In this case, a contact hole OPpca exposing a part of the connection electrode DE is formed in the first organic layer 181 such that the connection electrode DE can be connected to the anode Anode in a subsequent process.

Thereafter, the passivation layer PVX is laminated on the first organic layer 181 (S30). Here, the passivation layer PVX may include an inorganic material such as a silicon oxide (SiOₓ), a silicon nitride (SiNₓ), or a silicon oxynitride (SiOₓN_{y}).

Thereafter, a sacrificial layer SFL is laminated on the passivation layer PVX and then etched (S40). Here, the sacrificial layer SFL may be formed of an indium zinc oxide (IZO) or a transparent conductive material. After the sacrificial layer SFL is laminated on the passivation layer PVX, isotropic dry etching is performed in one direction. As a result, as shown in FIG. 11, the sacrificial layer SFL is all etched and removed, and the passivation layer PVX has a tip on one side near the contact hole OPpca.

After that, an anode Anode is formed on the passivation layer PVX (S50). The anode Anode is formed by laminating the conductive material for the anode and then patterning it using a mask. Meanwhile, the anode structure near the contact hole OPpca may not be etched with a separate mask, and may be formed only by layering conductive material for the anode. That is, when the conductive material for anode is laminated near the contact hole OPpca, as shown in FIG. 11, the anode Anoce-b is formed only on the part where the tip of the passivation layer PVX is formed, but in the vicinity where there is no tip, the anode Anode-r connected to the exposed connection electrode DE continuously through the contact hole OPpca is formed. The first anode Anode-r may also have a structure in which the first anode Anode-r formed on the tip of the passivation layer PVX above another adjacent contact hole OPpca and overlaps with another adjacent anode on a plane.

After that, the pixel definition layer 380 is formed above the anodes Anode-r and Anode-b and covers the contact hole OPpca (S60). Here, the pixel definition layer 380 may be formed of an organic material, and may be formed of a transparent organic material or a black color organic material. A space between adjacent pixel definition layers 380 forms an opening OP of the pixel definition layer 380.

After that, the separator SEP is formed with an organic material on the pixel definition layer 380 (S70). The separator SEP has a wider upper surface than the bottom surface, and a reverse tapered structure on the side. Due to the reverse tapered side, at least one layer may have a structure that is separated from each other based on the separator SEP. Here, the structure separated by the separator SEP may be a middle layer included in the light emitting element, and the capping layer located on the light emitting element may also be separated.

The separator SEP may be included when the emission layer uses a light emitting element displaying white. Therefore, when each light emitting element includes emission layers of different colors, the separator SEP may not be included.

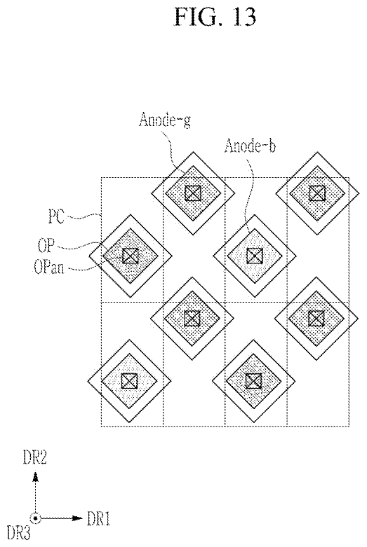

Hereinafter, embodiments in which a contact hole OPan overlaps the emission layer on a plane will be described with reference to FIG. 13 to FIG. 16.

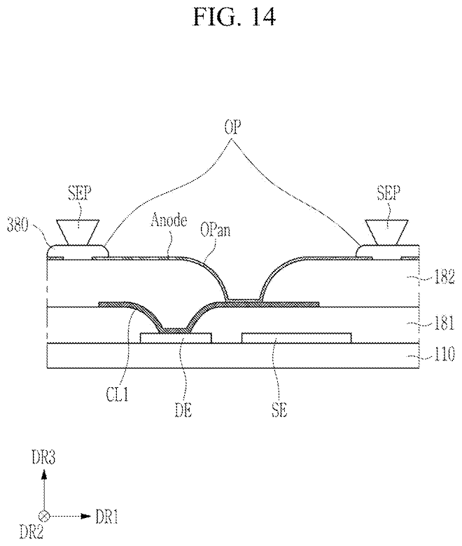

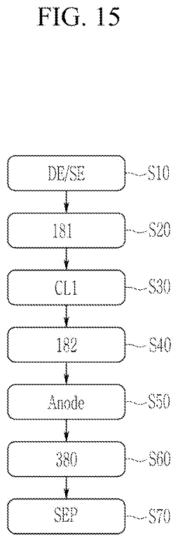

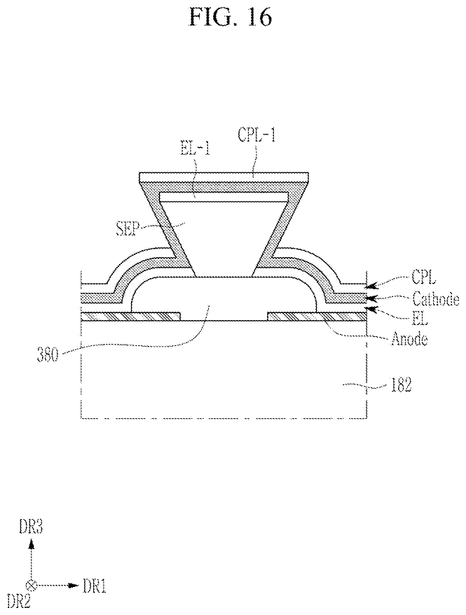

FIG. 13 is a top plan view of a display device according to some embodiments, FIG. 14 is a cross-sectional view of the embodiments of FIG. 13, FIG. 15 shows a manufacturing process of the display device according to the embodiments of FIG. 13, and FIG. 16 is an enlarged cross-sectional view of a part of the display device according to the embodiments of FIG. 13.

First, a planar structure will be described with reference to FIG. 13. In the planar structure of FIG. 13, an anode with a smaller area than the planar structure of FIG. 2 is shown. Referring to the cross-section diagram of FIG. 14, as a pixel definition layer 380 is additionally formed, a space between adjacent anodes may be wider than that in the embodiments of FIG. 2.

As shown in FIG. 2, in FIG. 13, a pixel driving circuit portion PC, anodes Anode-r, Anode-g, and Anode-b, an opening OP of a pixel definition layer 380 (refer to FIG. 14), and a contact hole OPan connecting the pixel driving circuit portion PC and one of the anodes Anode-r, Anode-g, and Anode-b are illustrated. The contact hole OPan has a structure overlapping the opening OP of the pixel definition layer 380 on a plane, and since an emission layer is located at the opening OP of the pixel definition layer 380, the contact hole OPpca and the light emitting element also overlap each other.

Referring to FIG. 14, not as shown in FIG. 3, the pixel definition layer 380 is further formed between the anode Anode and the separator SEP. The pixel definition layer 380 has a structure covering a portion of the anode Anode, and the opening OP of the pixel definition layer 380 overlaps the rest of the anode Anode.

Meanwhile, an upper surface of the separator SEP is wider than a bottom surface, and a side surface is formed in a reverse tapered structure. Due to the reverse tapered side, at least one layer may have a structure that is separated from each other based on the separator SEP. Due to the reverse tapered structure of the separator SEP, an organic material is disconnected without being connected, and the cathode is positioned on the side of the separator SEP by using damage free sputter equipment with a relatively low incident angle, and may have a structure that goes over the separator SEP.

The separator SEP may be included when the emission layer uses a light emitting element displaying white. Therefore, when each light emitting element includes emission layers of different colors, the separator SEP may not be included.

The structure shown in FIG. 13 and FIG. 14 may be manufactured through a manufacturing method of FIG. 15.

Referring to FIG. 15, the first data conductive layer including the connection electrodes SE and DE that can be connected to the first region and second region of the transistor is formed on the substrate 110 (S10). The first data conductive layer may include a metal such as aluminum (Al), copper (Cu), molybdenum (Mo), titanium (Ti), and the like or a metal alloy thereof, and may be formed of a single layer or multiple layers.

Thereafter, a first organic layer 181 is laminated on the first data conductive layer (S20). The first organic layer 181 may include at least one material selected from a group consisting of polyimide, polyamide, acryl resin, benzocyclobutene, and phenol resin. In this case, an opening exposing a portion of the connection electrode DE is formed in the first organic layer 181 such that it can be connected to an anode connection line CL1 in a subsequent process.

After that, a second data conductive layer including the anode connection line CL1 is formed on the first organic layer 181 (S30). The second data conductive layer may include a metal such as aluminum (Al), copper (Cu), molybdenum (Mo), titanium (Ti), and the like or a metal alloy thereof, and may be formed of a single layer or multiple layers. The anode connection line CL1 is connected to the connection electrode DE through an opening formed in the first organic layer 181.

After that, a second organic layer 182 is laminated on the second data conductive layer (S40). The second organic layer 182 may include at least one material selected from a group consisting of polyimide, polyamide, acryl resin, benzocyclobutene, and phenol resin. In this case, a contact hole OPan exposing a part of the anode connection line CL1 is formed in the second organic layer 182 and thus it may be connected to the anode Anode in a subsequent process.

After that, after laminating a conductive material for an anode on the second organic layer 182, the conductive material is etched with a mask to form the anode Anode (S50).

After that, the pixel definition layer 380 is formed on the anodes Anode-r and Anode-b (S60). Here, the pixel definition layer 380 may be formed of an organic material, and may be formed of a transparent organic material or a black color organic material. A space between adjacent pixel definition layers 380 forms the opening OP of the pixel definition layer 380.

After that, the separator SEP is formed with an organic material on the pixel definition layer 380 (S70). The separator SEP has a wider upper surface than the bottom surface, and a reverse tapered structure on the side. Due to the reverse tapered side, at least one layer may have a structure that is separated based on the separator SEP. Here, the structure separated by the separator SEP may be a middle layer included in the light emitting element, and the capping layer located on the light emitting element may also be separated.

Meanwhile, according to some embodiments, the forming the second data conductive layer including the anode connection line CL1 (S30) and the stacking the second organic layer 182 (S40) may be omitted.

FIG. 13 to FIG. 15 shows only the separator SEP and the anode Anode, and the light emitting element further includes a middle layer EL including an emission layer, and a cathode Cathode in addition to the anode Anode. The overall structure of this light emitting element will be described with reference to FIG. 16.

FIG. 16 is an enlarged view of the structure above the second organic layer 182, and the pixel definition layer 380, the separator SEP, and the light emitting element are formed on the second organic layer 182, and the capping layer CPL is formed thereon.

Specifically, the pixel definition layer 380 and the anode Anode of the light emitting element are formed on the second organic layer 182, and the separator SEP having a reverse tapered side is formed on the pixel definition layer 380.

In addition, the middle layer EL including the emission layer is located above the anode Anode and above the pixel definition layer 380, and a part of the middle layer, EL-1, is located on the upper surface of the separator SEP. The part EL-1 of the middle layer located on the upper surface of the separator SEP may not be located on the side of the separator SEP. Here, the emission layer may include an emission layer displaying a white color.

The middle layer EL including the emission layer located on the anode Anode and the pixel definition layer 380 may be specifically divided into a first functional layer, an emission layer, and a second functional layer

The first functional layer is located between the anode and the emission layer, and the second functional layer is located above the emission layer. The first functional layer located below the emission layer may include a hole injection layer and/or hole transport layer, and the second functional layer located above the emission layer may include an electron transport layer and/or electron injection layer. Here, the first functional layer and the second functional layer may contact each other in a region where the emission layer is not located, that is, in a part of the upper surface of the pixel definition layer 380.

According to some embodiments, the part EL-1 of the middle layer positioned on an upper surface of the separator SEP may not include an emission layer.

The cathode Cathode is positioned on the middle layer, and the cathode may have a structure in which it is also located on a side of the separator SEP by using damage free sputter equipment with a relatively low incident angle, and extends over the separator SEP and connected at both sides of the separator SEP.

The capping layers CPL and CPL-1 are located on the cathode Cathode, and the capping layers are separated based on the separator SEP, and thus the capping layer CPL-1 is located on the upper surface of the separator SEP and the capping layer CPL is located on a part that does not overlap with the separator SEP.

An encapsulation layer may be located on the capping layers CPL and CPL-1, and when the light emitting element is a light emitting element displaying white color, red, green, and blue color filters may be additionally formed.

Meanwhile, according to some embodiments, the anode Anode may be formed on the side of the separator SEP as shown in FIG. 6 to FIG. 9.

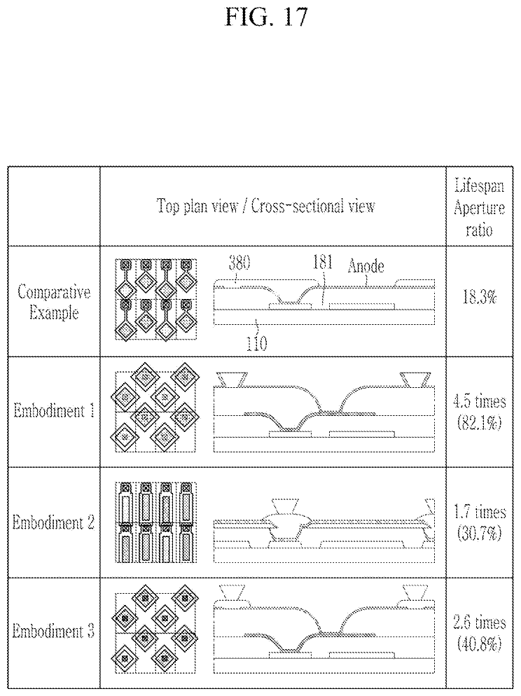

Hereinafter, the effect of the present disclosure will be described in comparison with one comparative example and three embodiments with reference to FIG. 17.

FIG. 17 is a drawing for comparing and describing a comparative example and embodiments.

First, in FIG. 17, Embodiment 1 in FIG. 17 corresponds to the embodiments of FIG. 2 and FIG. 3, Embodiment 2 corresponds to the embodiments of FIG. 10 and FIG. 11, and Embodiment 3 corresponds to the embodiments of FIG. 13 and FIG. 14. The comparative example of FIG. 17 is an example in which an emission layer located on an anode Anode does not overlap a contact hole that is connected with the anode Anode and a pixel driving circuit portion PC on a plane, and a space between adjacent anodes Anodes is not formed to a minimum.

Referring to FIG. 17, in the case of the comparative example, the area of the light emitting element is not large and thus it can be confirmed that the lifetime aperture ratio value is as low as 18.3%. Here, the lifetime aperture ratio is an aperture ratio corresponding to the area of the light emitting element, and in the case of a light emitting element, the lifetime of the emission layer is related to the aperture ratio, and thus it is named the lifetime aperture ratio. When the light emitting element has a large aperture ratio, it has the merit of extending its lifespan as it can apply less current when displaying the same luminance. In addition, the larger the lifetime aperture ratio, the higher the maximum displayable luminance.

Unlike the comparative example, it can be confirmed that Embodiments 1 to 3 have high lifetime aperture ratio values of 82.1%, 30.7%, and 40.8%, respectively.

Among Embodiments, Embodiment 2 has the lowest lifetime aperture ratio increase, but it can be confirmed that it is improved by 1.7 times compared to the comparative example. As a result, when the display device of Embodiment 2 is used for a head-mounted display device, 1.7 times improved luminance can be displayed compared to the comparative example.

On the other hand, Embodiment 3 may display 2.6 times the luminance compared to the comparative example, and Embodiment 1 has the characteristics of Embodiment 2 (forming the anode as large as possible and overlapping with the adjacent anode on a plane) and the characteristics of Embodiment 3 (emission layer and contact hole overlap) and thus it is possible to improve luminance by 4.5 times compared to the comparative example.

In Embodiment 1, a space between adjacent anodes is measured to be at least 3 μm, but in the case of the comparative example, a space between anodes is at least 5 μm, and thus the space between anodes can be drastically reduced, thereby greatly increasing the area of the light emitting element.

Hereinabove, various embodiments and the characteristics of the aperture ratio accordingly have been described.

Hereinafter, a cross-sectional structure of the entire display device will be described for detailed description of an upper structure of a display device.

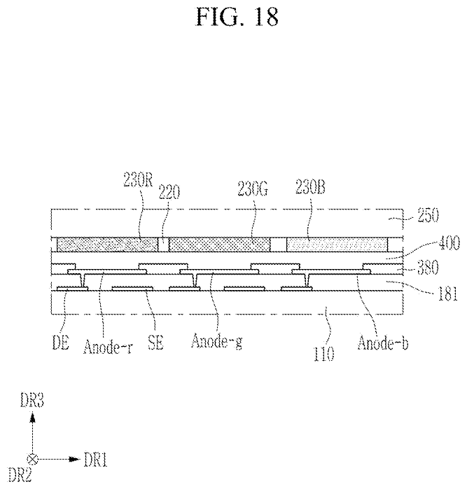

FIG. 18 is a schematic entire cross-sectional view of a display device according to some embodiments.

Like other cross-sectional views, in FIG. 18, an area between a substrate 110 and a first data conductive layer including connection electrodes SE and DE is not shown.

A structure between the substrate 110 and the first data conductive layer including the connection electrodes SE and DE according to some embodiments may be described as follows.

The substrate 110 may include a material that has a rigid characteristic such as glass and does not bend, or may include a flexible material that can bend, such as plastic or polyimide. In the case of a flexible substrate, a double-layered structure of polyimide and a barrier layer formed of an inorganic insulating material thereon may be repeatedly formed.

A buffer layer covering it is positioned on the substrate 110. The buffer layer serves to block the penetration of impurity elements into a first semiconductor layer, and may be an inorganic insulation layer including a silicon oxide (SiOₓ), a silicon nitride (SiNₓ), or s silicon oxynitride (SiOₓN_{y}).

According to some embodiments, a lower shielding layer including a metal and overlapping a channel of a transistor may be further included between the substrate 110 and the buffer layer.

Above the buffer layer, a first semiconductor layer formed of a silicon semiconductor (e.g. a polycrystalline semiconductor (P—Si)) is positioned. The first semiconductor layer includes a channel of a polycrystalline transistor including a driving transistor and a first region and a second region positioned on both sides of the channel. Here, the polycrystalline transistor may be another switching transistor as well as a driving transistor. In addition, both sides of the channel of the first semiconductor layer have regions having a conductive layer characteristic by plasma treatment or doping, and thus they may serve as first electrode and a second electrode of the transistor.

A first gate insulation layer may be positioned on the first semiconductor layer. The first gate insulation layer may be an inorganic insulation layer including a silicon oxide (SiOₓ), a silicon nitride (SiNₓ), a silicon oxynitride (SiOₓN_{y}), and the like.

A first gate conductive layer including a gate electrode of a polycrystalline transistor may be positioned on the first gate insulation layer. In addition to the gate electrode of the polycrystalline transistor, a scan line or light emitting control line may be formed in the first gate conductive layer.

After forming the first gate conductive layer, an exposed region of the first semiconductor layer may be made conductive by performing a plasma treatment or doping process. That is, the first semiconductor layer covered by the gate electrode is not conductive, and a portion of the first semiconductor layer not covered by the gate electrode may have the same characteristics as the conductive layer.

A second gate insulation layer may be positioned on the first gate conductive layer and the first gate insulation layer. The second gate insulation layer may be an inorganic insulation layer including a silicon oxide (SiOₓ), a silicon nitride (SiNₓ), a silicon oxynitride (SiOₓN_{y}), and the like.

A second gate conductive layer including one electrode of a first capacitor may be positioned on the second gate insulation layer. One electrode of the first capacitor may overlap the gate electrode of the driving transistor to form a first capacitor.

A first interlayer insulation layer may be positioned on the second gate conductive layer. The first interlayer insulation layer may include an inorganic insulation layer including a silicon oxide (SiOₓ), a silicon nitride (SiNₓ), a silicon oxynitride (SiOₓN_{y}), and the like, and according to some embodiments, the inorganic insulating material may be formed thickly.

A first data conductive layer including connection electrodes SE and DE that may be connected to the first region and the second region of the polycrystalline transistor may be positioned on the first interlayer insulation layer. The first data conductive layer may include a metal or metal alloy such as aluminum (Al), copper (Cu), molybdenum (Mo), titanium (Ti), and the like, and may be formed of a single layer or multiple layers.

Meanwhile, according to some embodiments, an oxide transistor may be included between the first interlayer insulation layer and the first data conductive layer, and the oxide transistor may be formed as a layered structure as follows.

A second semiconductor layer (oxide semiconductor layer) including a second semiconductor including a channel, a first region, and a second region of the oxide transistor may be positioned on the first interlayer insulation layer. A third gate insulation layer may be positioned on the second semiconductor layer. The third gate insulation layer may be positioned on the entire surface above the second semiconductor layer and the first interlayer insulation layer. A third gate conductive layer including a gate electrode of the oxide transistor may be positioned on the third gate insulation layer. The gate electrode of the oxide transistor may overlap the channel, and the third gate conductive layer may further include a scan line or control line. A second interlayer insulation layer may be positioned on the third gate conductive layer.

As shown in FIG. 18, a first organic layer 181 may be positioned on the first data conductive layer including connection electrodes SE and DE. The first organic layer 181 may be an organic insulator including an organic material, and the organic material may include at least one material selected from a group consisting of polyimide, polyamide, acryl resin, benzocyclobutene, and phenol resin.

Anodes Anode-r, Anode-g, and Anode-b are formed above the first organic layer 181. An additional data conductive layer or organic layer may be positioned further between the first organic layer 181 and the anodes Anode-r, Anode-g, and Anode-b according to some embodiments.

The structure on the first organic layer 181 and the anodes Anode-r, Anode-g, and Anode-b may vary for each embodiment, and FIG. 18 shows a pixel definition layer 380 as one of the structures. The pixel definition layer 380 may be a black pixel definition layer formed of an organic material having a black color such that light applied from the outside is not reflected back to the outside, and may be formed of a transparent organic material according to some embodiments. Meanwhile, according to some embodiments, a spacer may be further formed on the pixel definition layer 380.

According to some embodiments, a separator may be positioned instead of the pixel definition layer 380, and the separator may be positioned on the pixel definition layer 380. In addition, a middle layer including an emission layer and a cathode are positioned on the anodes Anode-r, Anode-g, and Anode-b, but is omitted in FIG. 18.

A light emitting element including the anodes Anode-r, Anode-g, and Anode-b, the middle layer, and the cathode may be a white light emitting element emitting white color, and an encapsulation layer 400 is positioned on the light emitting element. The encapsulation layer 400 includes at least one inorganic layer and at least one organic layer, and may have a triple-layered structure including a first inorganic encapsulation layer, an organic encapsulation layer, and a second inorganic encapsulation layer. The encapsulation layer 400 may be for protecting an emission layer from moisture or oxygen that may inflow from the outside. According to some embodiments, the encapsulation layer 400 may include a structure in which an inorganic layer and an organic layer are sequentially stacked.

A light blocking layer 220 and color filters 230R, 230G, and 230B are located on the encapsulation layer 400. The color filters 230R, 230G, and 230B allow each light emitting element to display a color when the light emitting element emits a white color, enabling color display. Meanwhile, according to some embodiments, each light emitting element may display one of three primary colors, in which case the color filter may be omitted. According to some embodiments, when the light emitting element emits blue light, a color conversion layer may be further included to convert blue light into red or green to display a color.

The light blocking layer 220 may serve to block light such that light passing through the color filters 230R, 230G, and 230B does not mix with each other.

According to some embodiments, a module portion 250 that includes a sensing insulation layer and a plurality of sense electrodes may be located on the light blocking layer 220 and the color filters 230R, 230G, and 230B for sensing a touch.

According to some embodiments, a film containing a polarizer may be attached to reduce reflection of external light on the module portion 250, or a layer in which a material that can absorb some wavelengths of external light (hereinafter, referred to as a reflection control material) is formed may be further included on the module portion 250.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims, and their equivalents.

Description of Some of the Reference Symbols

| | |
|---|---|
| 100: display device | 200: optical system |
| 201: first curved lens | 202: second curved lens |
| 110: substrate | 181: first organic layer |
| 182: second organic layer | OPan, OPpca: contact hole |
| PC: pixel driving circuit portion | |
| Anode′: conductive material for anode | |
| Anode, Anode-1, Anode-r, Anode-g, | |
| Anode-b: anode | |
| Cathode: cathode | EL, EL-1: middle layer |
| INO: inorganic insulation layer | SEP: separator |
| OP-SEP: opening for separator | CL1: anode connection line |
| CPL, CPL-1: capping layer | PVX: passivation layer |
| SE, DE: connection electrode | SFL: sacrificial layer |
| TPL, TPL-1: top protective layer | Tip: tip |
| Wan: width | 380: pixel definition layer |
| OP: opening for pixel definition layer | 220: light blocking layer |
| 230R, 230G, 230B: color filter | 250: module portion |
| 400: encapsulation layer | |

What is claimed is:

1. A display device comprising:
a substrate;
a pixel circuit driving portion on the substrate;
an organic layer that covers the pixel circuit driving portion;
a light emitting element on the organic layer and including an anode; and
a separator including a reverse tapered side on the organic layer,
wherein a width of a bottom surface of the separator is equal to a distance between adjacent anodes.

2. The display device of claim 1, wherein:
the organic layer comprises a contact hole connecting the pixel circuit driving portion and the anode, and
the light emitting element overlaps the contact hole in a plan view.

3. The display device of claim 2, wherein:
the separator and the contact hole do not overlap in the plan view.

4. The display device of claim 2, wherein:
the anode has a step at a periphery of the contact hole.

5. The display device of claim 4, further comprising an anode connection line that is covered by the organic layer, and connects the anode and the pixel circuit driving portion.

6. The display device of claim 5, further comprising an inorganic insulation layer that is only on the reverse tapered side of the separator.

7. The display device of claim 5, wherein:
the light emitting element further comprises a middle layer on the anode and includes an emission layer, and a cathode,
wherein the middle layer is not on the reverse tapered side of the separator and is separated based on the separator, and
the cathode is also on the reverse tapered side of the separator and is connected to each other on both sides of the separator.

8. The display device of claim 7, wherein:
a portion of the middle layer is on an upper surface of the separator.

9. The display device of claim 8, further comprising a capping layer on the cathode,
wherein the capping layer is not on the reverse tapered side of the separator and is separated based on the separator.

10. The display device of claim 6, wherein:
the anode is also between the reverse tapered side of the separator and the inorganic insulation layer.

11. The display device of claim 10, wherein:
the light emitting element further comprises a middle layer on the anode and including an emission layer, and a cathode,
the middle layer is not on the reverse tapered side of the separator and is separated based on the separator, and
the cathode is also on the reverse tapered side of the separator and connected to each other on both sides of the separator.

12. The display device of claim 11, wherein:
a portion of the middle layer is on an upper surface of the separator.

13. The display device of claim 10, further comprising a top protective layer that is between the anode on the reverse tapered side of the separator and the inorganic insulation layer.

14. The display device of claim 13, wherein:
an upper protective layer has a lower height than the anode and the inorganic insulation layer on the reverse tapered side of the separator.

15. A display device comprising:
a substrate;
a pixel circuit driving portion on the substrate;
an organic layer covering the pixel circuit driving portion;
an anode on the organic layer;
a pixel definition layer on the organic layer and covering a part of the anode; and
a separator on the pixel definition layer, and including a reverse tapered side,
wherein the organic layer comprises a contact hole connecting the pixel circuit driving portion and the anode, and
the pixel definition layer and the separator do not overlap the contact hole in a plan view.

16. The display device of claim 15, further comprising a middle layer on the anode and including an emission layer, and a cathode,
wherein the middle layer is on the pixel definition layer, but is not on the reverse tapered side of the separator and thus is separated based on the separator, and
the cathode is above the pixel definition layer and also on the reverse tapered side of the separator, and thus connected to each other on both sides of the separator.

17. The display device of claim 16, wherein:
a portion of the middle layer is on an upper surface of the separator.

18. A display device comprising:
a substrate;
a first pixel circuit driving portion on the substrate;
an organic layer covering the first pixel circuit driving portion; and
a first anode and a second anode on the organic layer, the first anode connected with the first pixel circuit driving portion and the second anode adjacent to the first anode,
wherein the organic layer comprises a contact hole connecting the first pixel circuit driving portion and the first anode, and
the first anode and the second anode overlap each other on the contact hole in a plan view.

19. The display device of claim 18, further comprising a first passivation layer and a second passivation layer respectively between the organic layer and the first anode and between the organic layer and the second anode,
wherein a tip is formed at an end of the second passivation layer, and
the end of the second passivation layer overlaps the contact hole in the plan view.

20. The display device of claim 19, further comprising:
a pixel definition layer on the organic layer and covering the first anode and a part of the second anode; and
a separator on the pixel definition layer and having a reverse tapered side,
wherein the pixel definition layer and the separator overlap the contact hole in the plan view.
